(19) United States
(12) Patent Application Publication
(10) Pub. No.: US 2021/0359090 A1
(43) Pub. Date: Nov. 18, 2021

(54) TRANSISTOR STRUCTURE, GOA CIRCUIT, AND DISPLAY PANEL

(71) Applicant: Shenzhen China Star Optoelectronics Semiconductor Display Technology Co., Ltd., Shenzhen, Guangdong (CN)

(72) Inventor: Suping XI, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/981,308

(22) PCT Filed: Jun. 16, 2020
(86) PCT No.: PCT/CN2020/096241

§ 371 Date: Sep. 16, 2020

(30) Foreign Application Priority Data
May 13, 2020 (CN) 202010403049.7

(51) Int. Cl. H01L 29/417; H01L 27/12; H01L 29/423; H01L 29/786

(52) U.S. Cl. CPC H01L 29/41733; H01L 29/78696; H01L 29/42384; H01L 27/1222

(57) ABSTRACT

A transistor structure, a gate on array (GOA) circuit, and a display panel are provided. The transistor structure includes a substrate, and a source/drain electrode layer and a passivation layer which are disposed on the substrate sequentially. Furthermore, the source/drain electrode layer includes a source electrode and a drain electrode, and the source electrode is arranged around the drain electrode and is in an annular shape. The passivation layer includes a via hole. A projection of the drain electrode on the passivation layer covers the via hole.

### FIELD OF INVENTION

The present disclosure relates to the field of display technology, and specifically relates to a transistor structure, a gate on array (GOA) circuit, and a display panel.

### BACKGROUND OF INVENTION

With development of display technology, pixel values of current display screens are increasingly high, and bezels of the display screens are increasingly narrow. Furthermore, in the display screens, larger dimensions of transistors can cause areas of light shielding regions to become large, so that corresponding areas of light transmissive regions become smaller, thereby affecting aperture ratios of pixel units. When gate on array (GOA) driving technology is adopted, dimensions of the transistors can also affect dimensions of the bezels of the display screens. If the dimensions of the transistors are large, the bezels can be large therewith. Therefore, the dimensions of the transistors can limit the aperture ratios of the pixel units and the dimensions of the bezels when the gate electrode driving circuits are integrated and manufactured on array substrates.

In the display screens, if dimensions of transistors located in display regions are large, the aperture ratios of the pixel units can be affected. Meanwhile, if dimensions of transistors located in the GOA circuits are large, the dimensions of the bezels of the display screens can be affected. Therefore, how to reduce the dimensions in the display screens is an urgent problem to be solved.

### SUMMARY OF INVENTION

Embodiments of the present disclosure provide a transistor structure, a gate on array (GOA) circuit, and a display panel, which are able to effectively reduce dimensions of the transistor structure.

The present disclosure provides a transistor structure, including a substrate, and a source/drain electrode layer and a passivation layer which are disposed on the substrate sequentially.

Furthermore, the source/drain electrode layer includes a source electrode and a drain electrode, and the source electrode is arranged around the drain electrode and is in an annular shape. The passivation layer includes a via hole. A projection of the drain electrode on the passivation layer covers the via hole.

In the transistor structure provided by the present disclosure, the via hole corresponds to a middle region located on the drain electrode.

In the transistor structure provided by the present disclosure, the transistor structure includes a gate electrode layer. The gate electrode layer is disposed on the substrate. The gate electrode layer includes a gate electrode, and the gate electrode is in an annular shape.

In the transistor structure provided by the present disclosure, a projection of the gate electrode on the substrate is arranged around a projection of the drain electrode on the substrate.

In the transistor structure provided by the present disclosure, the transistor structure is a top-gate structure or a bottom-gate structure.

In the transistor structure provided by the present disclosure, the transistor structure further includes an active layer. The active layer is disposed between the substrate and the source/drain electrode layer. The active layer includes a channel. The source electrode and the drain electrode directly contact to the channel to make the source electrode and the drain electrode electrically connect to the channel.

In the transistor structure provided by the present disclosure, the channel is in an annular shape and is arranged around the via hole correspondingly.

In the transistor structure provided by the present disclosure, a projection of the source electrode on the substrate and a projection of the drain electrode on the substrate at least partially overlap a projection of the channel on the substrate.

Correspondingly, the present disclosure further provides a gate on array (GOA) circuit, including a transistor structure. The transistor structure includes a substrate, and a source/drain electrode layer and a passivation layer which are disposed on the substrate sequentially.

Furthermore, the source/drain electrode layer includes a source electrode and a drain electrode, and the source electrode is arranged around the drain electrode and is in an annular shape. The passivation layer includes a via hole. A projection of the drain electrode on the passivation layer covers the via hole.

In the GOA circuit provided by the present disclosure, the via hole corresponds to a middle region located on the drain electrode.

In the GOA circuit provided by the present disclosure, by the present disclosure, the transistor structure further includes a gate electrode layer.

The gate electrode layer is disposed on the substrate. The gate electrode layer includes a gate electrode, and the gate electrode is in an annular shape.

In the GOA circuit provided by the present disclosure, a projection of the gate electrode on the substrate is arranged around a projection of the drain electrode on the substrate.

In the GOA circuit provided by the present disclosure, the transistor structure is a top-gate structure or a bottom-gate structure.

In the GOA circuit provided by the present disclosure, the transistor structure further includes an active layer. The active layer is disposed between the substrate and the source/drain electrode layer. The active layer includes a channel. The source electrode and the drain electrode directly contact to the channel to make the source electrode and the drain electrode electrically connect to the channel.

In the GOA circuit provided by the present disclosure, the channel is in an annular shape and is arranged around the via hole correspondingly.

In the GOA circuit provided by the present disclosure, a projection of the source electrode on the substrate and a projection of the drain electrode on the substrate at least partially overlap a projection of the channel on the substrate.

Correspondingly, the present disclosure further provides a display panel, including a transistor structure. The transistor structure includes a substrate, and a source/drain electrode layer and a passivation layer which are disposed on the substrate sequentially.

Furthermore, the source/drain electrode layer includes a source electrode and a drain electrode, and the source electrode is arranged around the drain electrode and is in an annular shape. The passivation layer includes a via hole. A projection of the drain electrode on the passivation layer covers the via hole.

In the display panel provided by the present disclosure, the via hole corresponds to a middle region located on the drain electrode.

In the display panel provided by the present disclosure, by the present disclosure, the transistor structure includes a gate electrode layer. The gate electrode layer is disposed on the substrate. The gate electrode layer includes a gate electrode, and the gate electrode is in an annular shape.

In the display panel provided by the present disclosure, the transistor structure further includes an active layer. The active layer is disposed between the substrate and the source/drain electrode layer. The active layer comprises a channel. The source electrode and the drain electrode directly contact to the channel to make the source electrode and the drain electrode electrically connect to the channel.

The present disclosure provides the transistor structure, the GOA circuit, and the display panel. The transistor structure includes the substrate, and the source/drain electrode layer and the passivation layer which are disposed on the substrate sequentially. The passivation layer includes the via hole. Furthermore, by configuring the source electrode into the annular shape around the drain electrode, the projection of the drain electrode on the passivation layer covers the via hole. Therefore, the via hole can be directly defined to correspond to the drain electrode with the source electrode arranged around, thereby reducing the dimensions of the transistor structure.

### DESCRIPTION OF DRAWINGS

To more clearly illustrate the technical solutions of the embodiments of the present disclosure, the accompanying figures of the present disclosure will be described in brief. Obviously, the accompanying figures described below are only part of the embodiments of the present disclosure, from which figures those skilled in the art can derive further figures without making any inventive efforts.

FIG. 1 is a first plane schematic diagram of a transistor structure provided by one embodiment of the present disclosure.

FIG. 2 is a first structural schematic diagram of the transistor structure provided by one embodiment of the present disclosure.

FIG. 3 is a second structural schematic diagram of the transistor structure provided by one embodiment of the present disclosure.

FIG. 4 is a third structural schematic diagram of the transistor structure provided by one embodiment of the present disclosure.

FIG. 5 is a fourth structural schematic diagram of the transistor structure provided by one embodiment of the present disclosure.

FIG. 6 is a fifth structural schematic diagram of the transistor structure provided by one embodiment of the present disclosure.

FIG. 7 is a sixth structural schematic diagram of the transistor structure provided by one embodiment of the present disclosure.

FIG. 8 is a second plane schematic diagram of the transistor structure provided by one embodiment of the present disclosure.

FIG. 9 is a seventh structural schematic diagram of the transistor structure provided by one embodiment of the present disclosure.

### DETAILED DESCRIPTION OF PREFERRED EMBODIMENTS

The technical solutions in the embodiments of the present disclosure are clearly and completely described in the following with reference to the accompanying drawings in the embodiments of the present disclosure. Obviously, the described embodiments are only part of the embodiments of the present disclosure, and are not all embodiments of the present disclosure. All other embodiments obtained by those skilled in the art based on the embodiments of the present disclosure without creative efforts are within the scope of the present disclosure.

In the description of the present disclosure, it is to be understood that the terms “first” and “second” are used for descriptive purposes only and are not to be understood as indicating or implying relative importance or implicitly indicating the number of the indicated technical characteristics. Therefore, the characteristics defined by “first” or “second” may include one or more of the described characteristics either explicitly or implicitly. Therefore, it should not be understood as a limitation on the present disclosure.

A transistor described in embodiments of the present disclosure can be a thin film transistor, a field-effect transistor, or other devices with the same characteristics, and the transistor is a P-type transistor or an N-type transistor. Wherein, the P-type transistor is conductive during a gate electrode in a low electric level and is cut off during the gate electrode in a high electric level, and the N-type transistor is conductive during a gate electrode in a high electric level and is cut off during the gate electrode in a low electric level.

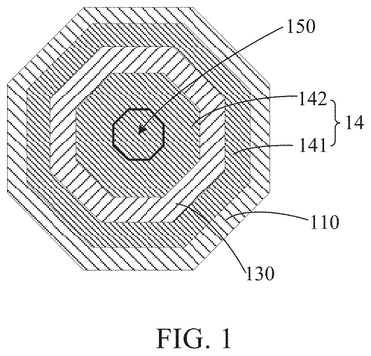

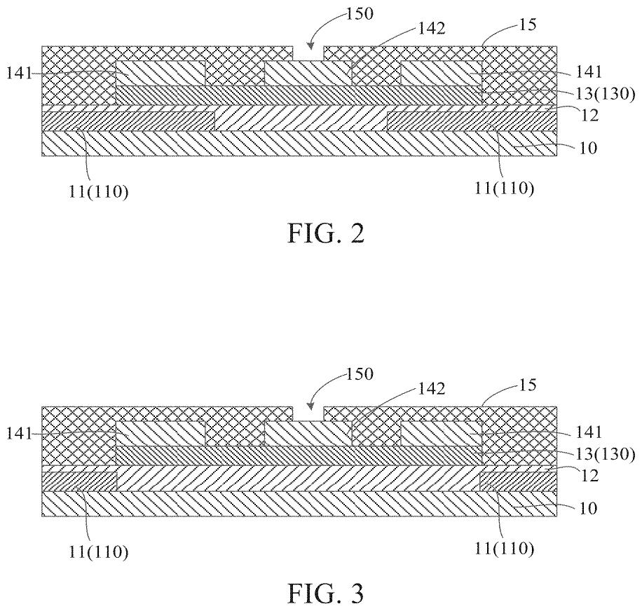

Please refer to FIG. 1 and FIG. 2, FIG. 1 is a first plane schematic diagram of a transistor structure provided by one embodiment of the present disclosure, and FIG. 2 is a first structural schematic diagram of the transistor structure provided by one embodiment of the present disclosure. As illustrated in FIG. 1 and FIG. 2, the transistor structure includes a substrate 10 and a source/drain electrode layer 14 and a passivation layer 15 which are disposed on the substrate 10 sequentially. Furthermore, the source/drain electrode layer 14 includes a source electrode 141 and a drain electrode 142. The source electrode 141 is arranged around the drain electrode 142, and the source electrode 141 is in an annular shape. The passivation layer 15 includes a via hole 150.

A projection of the drain electrode 142 on the passivation layer 15 covers the via hole 150.

It should be noted that the annular shape in the embodiment of the present disclosure can be a regular circular loop or a rectangular loop, and can be other irregular annular shapes. The drain electrode 142 can be a regular shape such as a circle, a rectangle, or an ellipse, and can be other irregular shapes, which are not specifically limited by the present disclosure.

Furthermore, the substrate 10 can be a glass substrate, a quartz substrate, a resin substrate, a polyimide (PI) flexible substrate, or other types of substrates. A material of the passivation layer 15 can be silica, silicon nitride, or a laminated structure of silica and silicon nitride. A material of the source/drain electrode layer 14 can be a metal with good conductivity, and is generally molybdenum, copper, aluminum, or a compound metal, which are not limited by the present disclosure.

By configuring the source electrode 141 into the annular shape around the drain electrode 142, the projection of the drain electrode 142 on the passivation layer covers the via hole 150, so that in the transistor structure provided by the embodiment of the present disclosure, the via hole 150 can be directly defined to correspond to the drain electrode 142 with the source electrode 141 arranged around, thereby reducing the dimensions of the transistor structure.

Furthermore, the via hole 150 corresponds to a middle region located on the drain electrode 142. In some embodiments, when the drain electrode 142 is a regular shape, such as a regular octagon as shown in FIG. 1, a projection of a central symmetrical point of the drain electrode 142 on the passivation layer 15 overlaps a center of a circle of the via hole 150. In some other embodiments, when the drain electrode 142 is an irregular shape, the via hole 150 is defined to correspond to a middle region of the drain electrode 142. The middle region specifically means a region where the drain electrode 142 is able to match a dimension of the via hole 150. This solution ensures that the drain electrode 142 can be electrically connected to a corresponding electrode line (not shown in the figure) through the via hole 150 to fully exert its effect, while reduces the area of the drain electrode as much as possible, thereby reducing the dimension of the transistor structure.

In one embodiment of the present disclosure, please continuously refer to FIG. 2, the transistor structure further includes a gate electrode layer 11. The gate electrode layer 11 is disposed on the substrate 10. The gate electrode layer 11 includes a gate electrode 110. The gate electrode 110 is in an annular shape.

Furthermore, a gate insulation layer 12 is disposed on a side of the gate electrode layer 11 away from the substrate 10. A material of the gate insulation layer 12 can be an inorganic material, such as silica, silicon nitride, or a combination of silica and silicon nitride, and can also be an organic material. A material of the gate electrode layer 11 can be a metal with good conductivity, and is generally molybdenum, copper, aluminum, or a compound metal, which are not limited by the present disclosure.

In some embodiments, a projection of the gate electrode 110 on the substrate 10 is arranged around a projection of the drain electrode 142 on the substrate 10. This solution makes a projection of the gate electrode 110 on the passivation layer 15 and the via hole 150 arrange in a staggered manner, preventing existed process error or stress generated from etch destroying the gate electrode 110 when the passivation layer 15 is etched to define the via hole 150.

Furthermore, please refer to FIG. 3, the projection of the gate electrode 110 on the substrate 10 is arranged around a projection of the source electrode 141 on the substrate 10. This solution makes the projection of the gate electrode 110 on the substrate 10 does not overlap the projection of the source electrode 141 on the substrate and the projection of the drain electrode 142 on the substrate 10, preventing parasitic capacitance generating, and improving stability of the transistor structure.

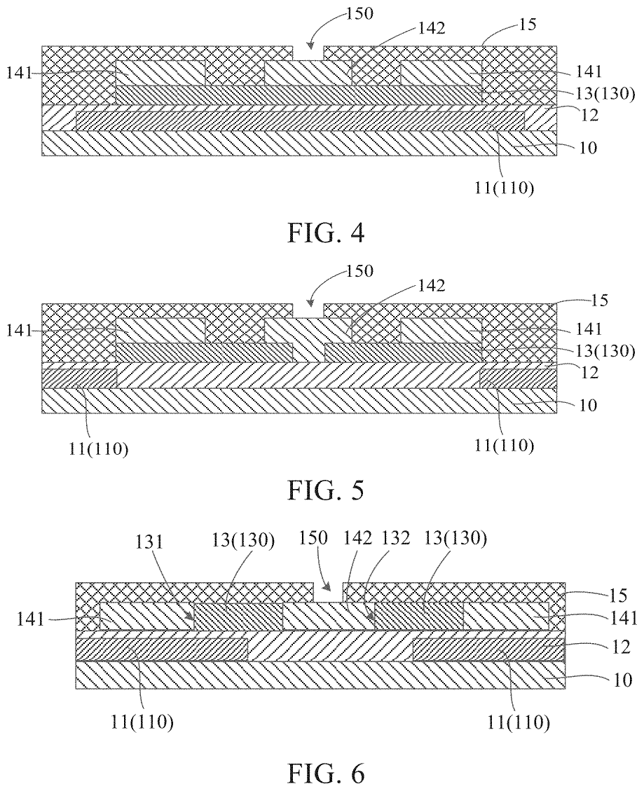

It should be noted that in several embodiments, please refer to FIG. 4, the gate electrode 110 can be a circular shape, a rectangular shape, or other shapes. Specifically, the projection of the gate electrode 110 on the substrate 10 can at least cover the projection of the source electrode 141 on the substrate 10 and the projection of the drain electrode 142 on the substrate 10.

Please continue referring to FIG. 2, the transistor structure further includes an active layer 13. The active layer 13 is disposed between the substrate 10 and the source/drain electrode layer 14. The active layer 13 includes a channel 130. Furthermore, the source electrode 141 and the drain electrode 142 directly contact to the channel 130 to make the source electrode 141, the drain electrode 142 be electrically connected to the channel 130.

Furthermore, a material of the active layer 13 includes amorphous silicon, low-temperature polycrystalline-silicon, and metal oxide semiconductor. It should be noted that the metal oxide semiconductor can be indium-gallium-zinc oxide, indium-tin-zinc oxide, indium-tin oxide, indium-zinc oxide, etc. The channel 130 can be a circular shape, a rectangular shape, or an annular shape, and in precondition of ensuring the source electrode 141 and the drain electrode 142 respectively connected and contacted to the channel 130, this is not limited by the present disclosure.

By disposing the source/drain electrode layer 14 on a lateral surface of the active layer 13 away from the substrate 10, the source electrode 141 and the drain electrode 142 are made to directly connect and contact to the channel 130 in the present disclosure, which omits steps of depositing an insulating layer on the channel 130 and etching a via hole on the insulating layer in the prior art, simplifies processes of the art, and improves production efficiency. Meanwhile, because the transistor structure is configured into a closed-loop shape, when the channel 130 meets the same channel width and length standards, the dimension of the transistor structure can be reduced.

Specifically, in some embodiments, the channel 130 is in a circular shape, a rectangular shape, an octagon shape, or other polygonal shapes. Please continue referring to FIG. 2, a projection of the channel 130 on the substrate 10 completely covers the projection of the source electrode 141 on the substrate 10 and the projection of the drain electrode 142 on the substrate 10, making the source electrode 141 and the drain electrode 142 is able to fully contact and connect to the channel 130.

In some embodiments, the channel 130 is in an annular shape, and the channel 130 is correspondingly arranged around the via hole 150. Please refer to FIG. 5, the projection of the channel 130 on the substrate 10 completely covers the projection of the source electrode 141 on the substrate 10, and the projection of the channel 130 on the substrate 10 partially overlaps the projection of the drain electrode 142 on the substrate 10. This solution makes a projection of the channel 130 on the passivation layer 15 and the via hole 150 arrange in a staggered manner, preventing existed process error destroying the gate electrode 110 when the passivation layer 15 is etched to define the via hole 150.

Furthermore, the projection of the source electrode 141 on the substrate 10 and the projection of the drain electrode 142 on the substrate 10 at least partially overlap the projection of the channel 130 on the substrate 10.

Specifically, please refer to FIG. 6, the channel 130 has a first lateral surface 131 and a second lateral surface 132. The source electrode 141 is contacted and connected to the first lateral surface 131, and the drain electrode 142 is contacted and connected to the second lateral surface 132. The channel 130, the source electrode 141, and the drain electrode 142 are disposed on a same layer in this configuration, which reduces a layer thickness of the transistor structure.

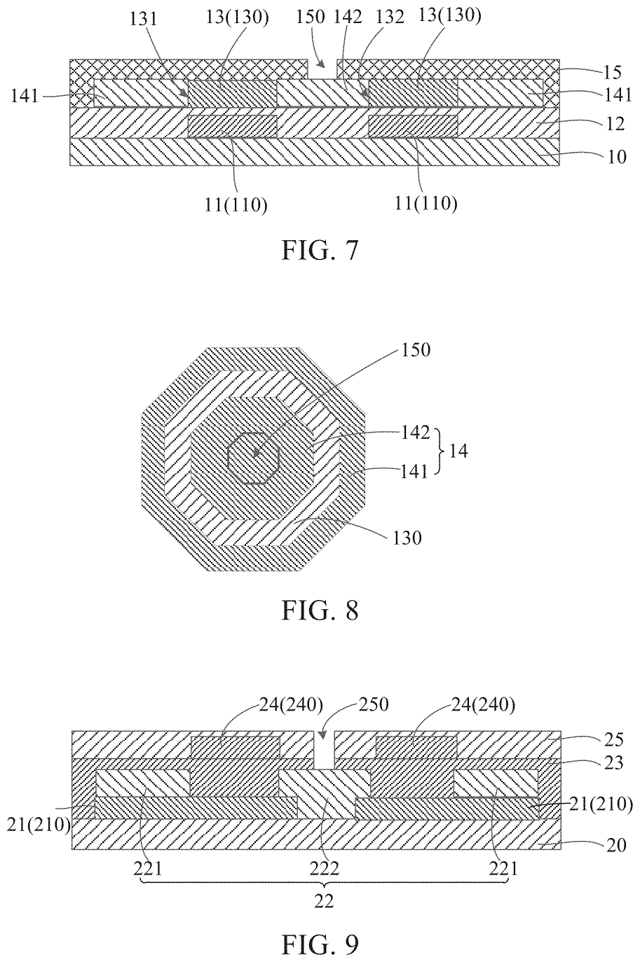

Furthermore, please refer to FIG. 7, the projection of the gate electrode 110 on the substrate 10 overlaps the projection of the channel 130 on the substrate 10. At this time, a second plane schematic diagram of the transistor structure is illustrated as FIG. 8. This solution further reduces the dimension of the transistor structure. Meanwhile, the projection of the gate electrode 110 on the substrate 10, the projection of the source electrode 141 on the substrate, the projection of the drain electrode 142 on the substrate 10 do not overlap with each other, preventing generation of parasitic capacitance, and improving stability of the transistor structure.

In one embodiment of the present disclosure, the transistor structure can be a top-gate structure or a bottom-gate structure. In some embodiments, please continue referring to FIG. 2, the transistor structure is the bottom-gate structure. Furthermore, the gate electrode layer 11 is disposed on the substrate 10. The gate electrode layer 11 includes the gate electrode 110. The gate insulation layer 12 is disposed in a stack on a side of the gate electrode layer 11 away from the substrate 10. The active layer 13 is disposed on a side of the gate insulation layer 12 away from the substrate 10. The active layer 13 includes the channel 130. The source/drain electrode layer 14 is disposed on a side of the active layer 13 away from the substrate 10. The source/drain electrode layer 14 includes the source electrode 141 and the drain electrode 142. The passivation layer 15 is disposed on the source electrode 141, the drain electrode 142, and the channel 130, and the via hole 150 is defined on the passivation layer 15. The via hole 150 penetrates the passivation layer 15 to expose a surface of the drain electrode 142 away from the substrate 20.

Furthermore, the source electrode 141 is arranged around the drain electrode 142, and the source electrode 141 is in the annular shape. The projection of the drain electrode 142 on the passivation layer 15 covers the via hole 150.

In some embodiments, please refer to FIG. 9, the transistor structure is the top-gate structure. Furthermore, an active layer 21 is disposed on a substrate 20. An active layer 21 includes a channel 210. A source/drain electrode layer 22 is disposed on a side of the active layer 21 away from the substrate 20. The source/drain electrode layer includes a source electrode 221 and the drain electrode 222. A gate insulation layer 23 is disposed on the active layer 21, the source/drain electrode layer 22, and the substrate 10. A gate electrode layer 24 is disposed on a side of the gate insulation layer 23 away from the substrate 20. The gate electrode layer 24 includes a gate electrode 240. A passivation layer 25 is disposed in the gate electrode layer 24 and the gate insulation layer 23, and a via hole 250 is defined on the passivation layer 25. The via hole 250 penetrates the passivation layer 25 and extends to the gate insulation layer 23 to expose a lateral surface of the drain electrode 222 away from the substrate 20. The via hole 250 corresponds to the drain electrode 222.

Furthermore, the source electrode 221 is arranged around the drain electrode 222, and the source electrode 221 is in an annular shape. A projection of the drain electrode 222 on the passivation layer 25 covers the via hole 250.

It should be noted that the specific structural description of the top-gate structure or the bottom-gate structure of the transistor structure mentioned above is only for understanding the technical solution of the present disclosure better, but cannot be understood as limitations to the present disclosure.

Correspondingly, the present disclosure provides a gate on array (GOA) circuit. The GOA circuit includes the transistor structure mentioned in any of above embodiments.

One embodiment of the present disclosure provides a GOA circuit. In the GOA circuit, by disposing a closed-loop transistor structure, configuring the source electrode in the annular shape arranged around the drain electrode, covering the via hole by the projection of the drain electrode of the passivation layer, and configuring the via hole contacted to the drain electrode to directly correspond to the drain electrode arranged around by the source electrode, the dimension of the transistor structure is reduced, and wiring space of the GOA circuit is effectively saved.

Correspondingly, the present disclosure provides a display panel. The display panel includes the transistor structure mentioned in any of above embodiments.

One embodiment of the present disclosure provides a display panel. In the display panel, by disposing a closed-loop transistor structure and configuring the source electrode in the annular shape arranged around the drain electrode, the projection of the drain electrode of the passivation layer covers the via hole, thereby can configure the via hole contacted to the drain electrode to directly correspond to the drain electrode arranged around by the source electrode, being able to reduce the dimension of the transistor structure, and increasing pixel aperture ratio. If a design of the GOA circuit is used in the display panel, dimensions of bezels of the display panel can effectively be reduced.

The above describes the embodiments of the present disclosure in detail. This article uses specific cases for describing the principles and the embodiments of the present disclosure, and the description of the embodiments mentioned above is only for helping to understand the method and the core idea of the present disclosure. Meanwhile, for those skilled in the art, will have various changes in specific embodiments and application scopes according to the idea of the present disclosure. In summary, the content of the specification should not be understood as limit to the present disclosure.

What is claimed is:

1. A transistor structure, comprising a substrate, and a source/drain electrode layer and a passivation layer which are disposed on the substrate sequentially,
wherein the source/drain electrode layer comprises a source electrode and a drain electrode, the source electrode is arranged around the drain electrode and is in an annular shape; the passivation layer comprises a via hole, and a projection of the drain electrode on the passivation layer covers the via hole.

2. The transistor structure as claimed in claim 1, wherein the via hole corresponds to a middle region located on the drain electrode.

3. The transistor structure as claimed in claim 1, wherein the transistor structure comprises a gate electrode layer, the gate electrode layer is disposed on the substrate, the gate electrode layer comprises a gate electrode, and the gate electrode is in an annular shape.

4. The transistor structure as claimed in claim 3, wherein a projection of the gate electrode on the substrate is arranged around a projection of the drain electrode on the substrate.

5. The transistor structure as claimed in claim 4, wherein the transistor structure is a top-gate structure or a bottom-gate structure.

6. The transistor structure as claimed in claim 1, wherein the transistor structure comprises an active layer, the active layer is disposed between the substrate and the source/drain electrode layer, the active layer comprises a channel, the source electrode and the drain electrode directly contact to the channel to make the source electrode and the drain electrode electrically connect to the channel.

7. The transistor structure as claimed in claim 6, wherein the channel is in an annular shape and is arranged around the via hole correspondingly.

8. The transistor structure as claimed in claim 6, wherein a projection of the source electrode on the substrate and a projection of the drain electrode on the substrate at least partially overlap a projection of the channel on the substrate.

9. A gate on array (GOA) circuit, comprising a transistor structure, wherein the transistor structure comprises a substrate, and a source/drain electrode layer and a passivation layer which are disposed on the substrate sequentially,
wherein the source/drain electrode layer comprises a source electrode and a drain electrode, the source electrode is arranged around the drain electrode and is in an annular shape; the passivation layer comprises a via hole, and a projection of the drain electrode on the passivation layer covers the via hole.

10. A GOA circuit as claimed in claim 9, wherein the via hole corresponds to a middle region located on the drain electrode.

11. A GOA circuit as claimed in claim 9, wherein the transistor structure comprises a gate electrode layer, the gate electrode layer is disposed on the substrate, the gate electrode layer comprises a gate electrode, and the gate electrode is in an annular shape.

12. A GOA circuit as claimed in claim 11, wherein a projection of the gate electrode on the substrate is arranged around a projection of the drain electrode on the substrate.

13. A GOA circuit as claimed in claim 12, wherein the transistor structure is a top-gate structure or a bottom-gate structure.

14. A GOA circuit as claimed in claim 9, wherein the transistor structure comprises an active layer, the active layer is disposed between the substrate and the source/drain electrode layer, the active layer comprises a channel, the source electrode and the drain electrode directly contact to the channel to make the source electrode and the drain electrode electrically connect to the channel.

15. A GOA circuit as claimed in claim 14, wherein the channel is in an annular shape and is arranged around the via hole correspondingly.

16. A GOA circuit as claimed in claim 14, wherein a projection of the source electrode on the substrate and a projection of the drain electrode on the substrate at least partially overlap a projection of the channel on the substrate.

17. A display panel, comprising a transistor structure, wherein the transistor structure comprises a substrate, and a source/drain electrode layer and a passivation layer which are disposed on the substrate sequentially,
wherein the source/drain electrode layer comprises a source electrode and a drain electrode, the source electrode is arranged around the drain electrode and is in an annular shape; the passivation layer comprises a via hole, and a projection of the drain electrode on the passivation layer covers the via hole.

18. The display panel as claimed in claim 17, wherein the via hole corresponds to a middle region located on the drain electrode.

19. The display panel as claimed in claim 17, wherein the transistor structure comprises a gate electrode layer, the gate electrode layer is disposed on the substrate, the gate electrode layer comprises a gate electrode, and the gate electrode is in an annular shape.

20. The display panel as claimed in claim 17, wherein the transistor structure comprises an active layer, the active layer is disposed between the substrate and the source/drain electrode layer, the active layer comprises a channel, the source electrode and the drain electrode directly contact to the channel to make the source electrode and the drain electrode electrically connect to the channel.
